(19) United States
(12) Patent Application Publication
(10) Pub. No.: US 2026/0225205 A1
(43) Pub. Date: Aug. 6, 2026

(54) POLISHING END POINT DETECTION DEVICE AND METHOD, AND CMP DEVICE

(71) Applicant: TOKYO SEIMITSU CO., LTD., Hachioji-shi, Tokyo (JP)

(72) Inventor: Shota NAKAHARA, Hachioji-shi, Tokyo (JP)

(21) Appl. No.: 19/153,324

(22) PCT Filed: Dec. 5, 2023
(86) PCT No.: PCT/JP2023/043520

§ 371 Date: Aug. 2, 2025

(30) Foreign Application Priority Data
Feb. 16, 2023 (JP) 2023-022960

(51) Int. Cl. B24B 37/013

(52) U.S. Cl. CPC B24B 37/013

(57) ABSTRACT

A polishing end point detection device includes a measuring section for irradiating a workpiece W with measurement light during polishing, and dispersing the reflected light from the workpiece to obtain a spectral waveform indicating the relationship between the wavelength of the reflected light and a reflectance. A detection section for calculating the thickness of a thermal oxide film by applying Fourier analysis to the spectral waveform. The reference intensity is calculated by bringing a sample workpiece exhibiting almost the same reflectance characteristics as the substrate of the workpiece into contact with a polishing pad with CMP slurry interposed between the sample workpiece and the rotating polishing pad, by irradiating the sample workpiece with measurement light through an observation window of the polishing pad by the measuring section, and by dispersing the reflected light from the sample workpiece.

### TECHNICAL FIELD

The present invention relates to a polishing end point detection device and method and a CMP device, and particularly to a polishing end point detection device for detecting the polishing end point when polishing a workpiece using chemical mechanical polishing (CMP) and to a CMP device.

### BACKGROUND ART

As a workpiece polishing device, a CMP polishing device that polishes a silicon dioxide film and the like formed on the substrate surface of a workpiece is known. Polishing by CMP is performed by, while rotating the polishing pad attached to a platen and the workpiece, pressing the workpiece against the polishing pad at a predetermined pressure, and by supplying a polishing material (slurry) between the polishing pad and the workpiece.

In such a CMP device, what is known is that fast Fourier transform (FFT) is used to extract the frequency components and their intensities from the reflectance spectrum generated based on the reflected light from the wafer and then the film thickness of the wafer is estimated from the obtained frequency components (see, for example, Patent Literature 1).

### CITATION LIST

### Patent Literature

Patent Literature 1: JP2019-30934A

### SUMMARY OF INVENTION

### Technical Problem

However, in the CMP device described in Patent Literature 1, where a reference spectrum is obtained in advance using a mirror in the presence of water and a reflectance spectrum showing the relationship between the wavelength of the reflected light from the wafer and the ratio of the intensity of the reflected light and the reference intensity (relative reflectance) is generated during wafer polishing, there is a problem that, for example, for thin workpieces whose thickness is 500 nm or less, the number of peaks contained in the reflectance spectrum is as few as one or two, making it impossible to calculate the film thickness of the wafer.

In addition, when the difference between the refractive index of the substrate and the refractive index of the layer to be polished is small, the amplitude of the reflectance spectrum is small, which is generally known, causing a problem of particular susceptibility to the thickness of the slurry during CMP polishing and to rotation.

Therefore, a technical problem arises that should be solved in order to accurately detect the polishing end point when polishing thin workpieces, and an object of the present invention is to solve this problem.

### Solution to Problem

In order to achieve the above-mentioned object, the polishing end point detection device according to the present invention is a polishing end point detection device for detecting the polishing end point when performing CMP polishing of the layer to be polished of a workpiece by bringing the workpiece into contact with a polishing pad, and includes a measuring section for irradiating the workpiece with measurement light during polishing of the workpiece, and dispersing the reflected light from the workpiece to obtain a spectral waveform indicating the relationship between the wavelength of the reflected light and a reflectance, which is the ratio of the intensity of the reflected light and the reference intensity for each wavelength component acquired in advance, and a detection section for calculating the film thickness of the layer to be polished based on the spectral waveform, wherein the reference intensity is calculated by bringing a sample workpiece exhibiting reflectance characteristics almost same as the workpiece into contact with the polishing pad with a slurry interposed between the sample workpiece and the rotating polishing pad, by irradiating the sample workpiece with measurement light through an observation window of the polishing pad by the measuring section, and by dispersing the reflected light from the sample workpiece.

Also, the CMP device according to the present invention includes the above-mentioned polishing end point detection device.

To achieve the above-mentioned object, the polishing end point detection method according to the present invention is a polishing end point detection method for detecting the polishing end point when performing CMP polishing of a layer to be polished of the workpiece by bringing the workpiece into contact with a polishing pad, and includes the step of irradiating the workpiece with measurement light during polishing of the workpiece, and dispersing the reflected light from the workpiece to obtain a spectral waveform that indicates the relationship between the wavelength of the reflected light and a reflectance, which is the ratio of the intensity of the reflected light and the reference intensity for each wavelength component acquired in advance, and the step of calculating the film thickness of the layer to be polished based on the spectral waveform, wherein the reference intensity is calculated by bringing a sample workpiece exhibiting reflectance characteristics almost same as the workpiece into contact with the polishing pad with a slurry interposed between the sample workpiece and the rotating polishing pad, by irradiating the sample workpiece with measurement light through an observation window of the polishing pad, and by dispersing the reflected light from the sample workpiece.

### Advantageous Effect of the Invention

The present invention enables accurate detection of the polishing end point of a thin workpiece by using a sample workpiece exhibiting reflectance characteristics almost same as the workpiece and calculating the reference intensity of the sample workpiece by unifying the reference measurement conditions, such as the presence or absence of a polishing agent in the slurry and the rotation or standstill of the platen, with the polishing conditions of CMP polishing.

### BRIEF DESCRIPTION OF DRAWINGS

FIG. 1 is a perspective view schematically showing a CMP device according to one embodiment of the present invention.

FIG. 2 is a longitudinal cross-sectional view schematically showing the key part of the polishing head.

FIG. 3 is a schematic diagram showing observation of the workpiece condition during processing.

FIG. 4 is a flowchart showing the procedure for detecting the polishing end point of the workpiece.

FIG. 5 shows spectral waveforms showing the relationship between the wavelength of reflected light and reflectance, which changes as polishing progresses.

FIG. 6 shows frequency spectra showing the relationship between the film thickness of the thermal oxide film and the intensity of the frequency components, which spectra are obtained by applying Fourier analysis to the spectral waveforms in FIG. 5.

FIG. 7 is a graph showing the trend of changes in the film thickness of the layer to be polished.

FIG. 8 is a graph after applying the optimization method to the graph in FIG. 7.

FIG. 9 shows spectral waveforms obtained in one embodiment of the present invention and the variants thereof.

FIG. 10 shows frequency spectra obtained from the spectral waveforms in FIG. 9.

FIG. 11 is a graph showing the trend of changes in the film thickness of the layer to be polished, obtained in the variants.

FIG. 12 shows spectral waveforms obtained in Comparative Example 1, which waveforms change as polishing progresses.

FIG. 13 shows frequency spectra obtained from the spectral waveform in FIG. 12.

FIG. 14 is a graph showing the trend of changes in the film thickness of the layer to be polished in Comparative Example 1.

FIG. 15 is a graph after applying the optimization method to the graph in FIG. 14.

FIG. 16 shows spectral waveforms obtained in one embodiment of the present invention and in Comparative Example 2.

FIG. 17 shows frequency spectra obtained from the spectral waveforms in FIG. 16.

FIG. 18 shows spectral waveforms obtained in one embodiment of the present invention and in Comparative Example 3.

### DESCRIPTION OF EMBODIMENT

The embodiment of the present invention will be described based on the drawings. In the following, when referring to the number, numerical value, quantity, range, or the like of components, it is not limited to that specific number, and may be more or less than that specific number, except in cases where it is specifically stated or where it is clearly limited to a specific number in principle.

Also, when referring to the shape or positional relationship of components or the like, it includes those that substantially approximate or resemble the shape or the like, except in cases such as when it is specifically stated or when it is clearly considered that this is not the case in principle.

In addition, drawings may be exaggerated by, for example, enlarging the characteristic part to make the features easier to understand, and the dimensional ratio or the like of the components is not always the same as the actual one. Also, in cross-sectional drawings, hatching of some components may be omitted to make the cross-sectional structure of the components easier to understand.

### CMP Device

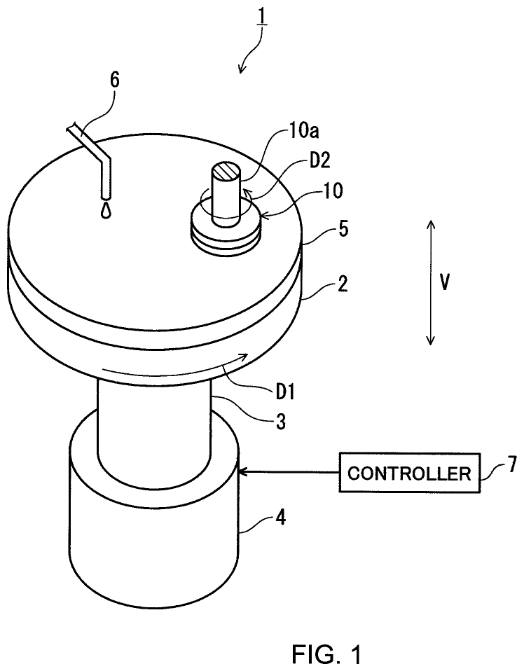

FIG. 1 is a perspective view schematically showing a CMP device 1 according to one embodiment of the present invention. The CMP device 1 includes a platen 2 and a polishing head 10.

The platen 2 is formed in a disk shape and is connected to a rotation axis 3 disposed below the platen 2. The rotation axis 3 rotates by the drive of a motor 4, so that the platen 2 rotates in the direction of arrow D1 in FIG. 1. A polishing pad 5 is affixed on the top surface of the platen 2, and a polishing agent and CMP slurry containing a chemical agent are supplied from a nozzle 6 onto the polishing pad 5.

The polishing head 10 is formed in a disk shape with a smaller diameter than the platen 2 and is connected to a rotation axis 10a disposed above the polishing head 10. The rotation axis 10a rotates by the drive of a motor (not shown), so that the polishing head 10 rotates in the direction of arrow D2 in FIG. 1. The polishing head 10 can be raised and lowered in the vertical direction V by a lifting device (not shown).

The operation of the CMP device 1 is controlled by a controller 7. The controller 7 controls each of the components constituting the CMP device 1. The controller 7 is, for example, a computer and is composed of a CPU, a memory, and the like. The functions of the controller 7 may be realized by controlling using software or by a thing that operates using hardware.

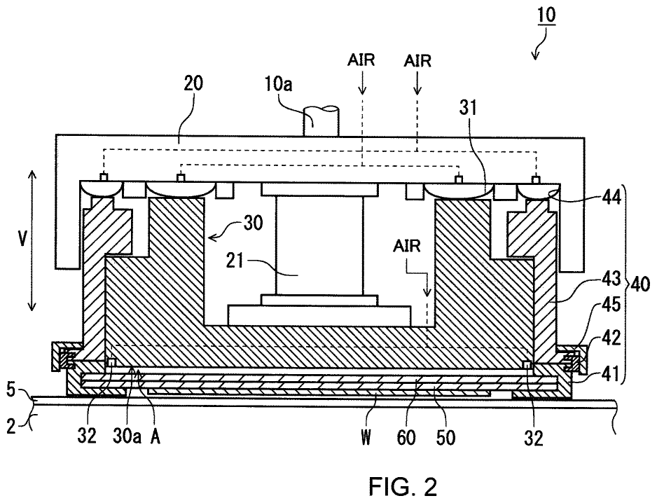

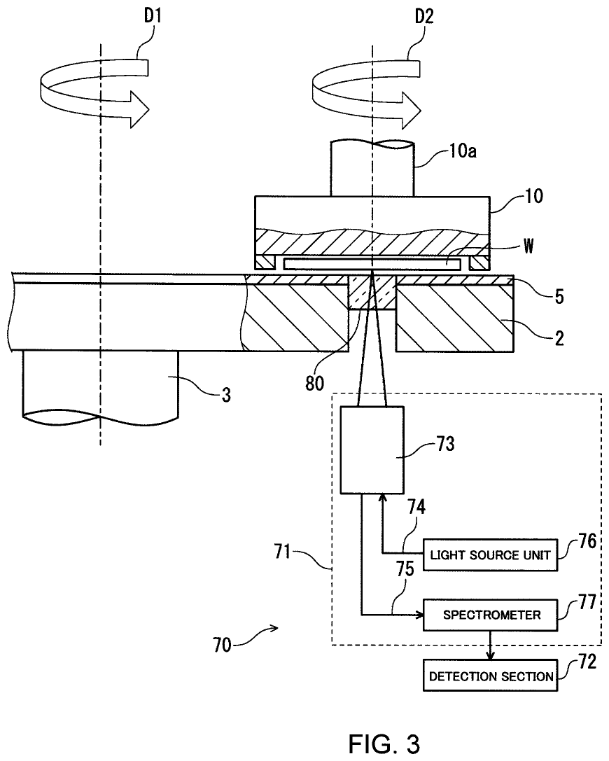

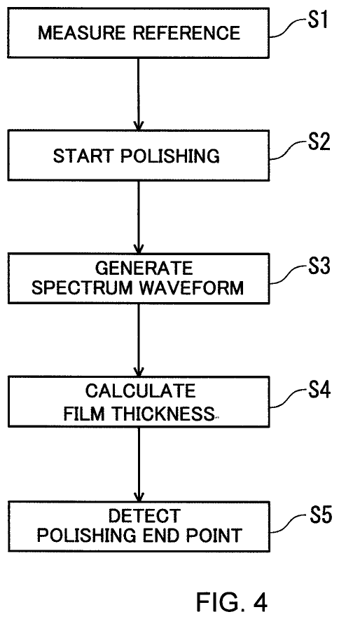

Next, the configuration of the polishing head 10 will be described based on FIG. 2, FIG. 3 and FIG. 4. As shown in FIG. 2, the polishing head 10 has a head body 20, a carrier 30, a retainer ring 40, a membrane film 50, and a backing film 60.

The head body 20 is connected to the rotation axis 10a and rotates together with the rotation axis 10a. The head body 20 is connected to the carrier 30 disposed below the head body 20 via a rotating section 21, and the head body 20 and the carrier 30 rotate in tandem.

Carrier pressing means 31 is provided between the head body 20 and the carrier 30. The carrier pressing means 31 is an airbag or the like that is inflated by air supplied from an air supply source (not shown). The pressure of the air supplied from the air supply source is adjusted by a regulator (not shown). The carrier pressing means 31 presses a workpiece W onto the polishing pad 5 via the carrier 30 according to the pressure of the supplied air.

The carrier 30 is provided with air lines 32 spaced at equal intervals on the circumferential edge of the carrier 30. The lower ends of the air lines 32 are open to an air chamber A formed between the lower surface 30a of the carrier 30 and the membrane film 50. The air lines 32 are connected to the air supply source (not shown) as air supply means, and air is introduced into the air chamber A via the air lines 32. The pressure of the air supplied to the air lines 32 is adjusted by the regulator (not shown). The air supplied from the air lines 32 to the air chamber A forms a pneumatic layer, which pushes back the pressure transmitted to the carrier 30 by the carrier pressing means 31, in the air chamber A and releases excess pressure into the atmosphere, so that the workpiece W can be pressed with uniform pressure distribution.

The lower surface 30a of the carrier 30 is provided with a plurality of elastic pressing members (not shown) disposed coaxially. Also, the plurality of pressing members are formed in the shapes of circular rings having diameters different from each other. The elastic pressing members are bolted to the lower surface 30a of the carrier 30 via brackets (not shown).

The elastic pressing members are disposed coaxially with the rotation axis 10a of the polishing head 10 and compartmentalize the air chamber A.

The retainer ring 40 is disposed so as to surround the periphery of the carrier 30. The retainer ring 40 has a frame 41, and on the top surface thereof, a membrane film 50 and a backing film 60 are provided.

The frame 41 is formed in the shape of a circular ring and has a housing pocket 41a for accommodating the workpiece W in the center. The frame 41 is attached to a retainer pressing member 43 via a snap ring 42. Retainer pressing means 44 is provided between the head body 20 and the retainer pressing member 43. It should be noted that the reference sign 45 denotes a cover covering the upper part of the snap ring 42.

The retainer pressing means 44 is an airbag or the like that is inflated by air supplied from the air supply source (not shown). The pressure of the air supplied from the air supply source is adjusted by the regulator (not shown). The retainer pressing means 44 presses the retainer ring 40 onto the polishing pad 5 via the retainer pressing means 44 in accordance with the pressure of the supplied air.

The membrane film 50 is made of a resin such as ethylene tetrafluoride perfluoroalkoxy vinyl ether copolymer (PFA) or polyethylene terephthalate (PET), for example. The membrane film 50 is bonded to the top surface of the backing film 60, and when compressed air is introduced into the air chamber A, the membrane film 50 is elastically deforms toward the inside of the housing pocket 41a by air pressure.

The backing film 60 is, for example, a suede film. The backing film 60 is affixed to the frame 41 so as to cover the housing pocket 41a, and when compressed air is introduced into the air chamber A, the backing film 60 elastically deforms due to the elastic deformation of the membrane film 50 to pressurize the workpiece W.

### Polishing End Point Detection Device

As shown in FIG. 3, the CMP device 1 has a polishing end point detection device 70 for detecting the polishing end point of the workpiece W during polishing. The polishing end point detection device 70 has a measuring section 71 and a detecting section 72. It should be noted that, in FIG. 3, the configuration of the CMP device 1 is partially omitted.

The measuring section 71 has a configuration in which, for example, a lens 73 is connected to a plurality of optical fibers 74 and 75 bound together. The optical fiber 74 is connected to a light source unit 76. The light source unit 76 is, for example, a halogen light source that emits white light having a wavelength of 400 to 800 nm, but is not limited thereto. The optical fiber 75 is connected to a spectrometer 77.

The lens 73 is disposed opposite to a transparent observation window 80 provided on the platen 2 and the polishing pad 5. The lens 73 is not limited to irradiating light perpendicularly to the observation window 80, and the light path may be refracted by a reflective member or the like. The observation window 80 is, for example, made of acrylic.

The measurement light emitted from the light source unit 76 passes through the optical fiber 74 and the lens 73, passes through the observation window 80, and is irradiated toward the layer to be polished of the workpiece W. Also, the reflected light reflected by the workpiece W and received by the lens 73 is guided to the spectrometer 77 through the optical fiber 75.

The respective reflected lights reflected on the surface of the layer to be polished and on the back surface of the layer to be polished (interface between the layer to be polished and the substrate) of the workpiece W interfere with each other, and the way of interference changes according to the film thickness (optical path length) of the layer to be polished. The spectrometer 77 decomposes the reflected lights from the workpiece W according to the wavelength and generates a spectral waveform showing the relationship between wavelength and reflectance. It should be noted that the reflectance is a numerical value obtained by dividing the intensity of the reflected light by the reference intensity described later.

The detection section 72 calculates the film thickness of the layer to be polished in the workpiece W being polished based on the spectral waveform generated by the spectrometer 77. As a method for calculating the film thickness of the layer to be polished based on the spectral waveform, for example, Fourier analysis can be used.

Specifically, the frequency component and its intensity are extracted from the Fourier series obtained from the spectral waveform, and the obtained frequency component is converted to the film thickness of the layer to be polished using a predetermined relational expression where the attenuation rate of the refractive index of the layer to be polished is taken into account.

### Polishing End Point Detection Method

Next, the procedure for detecting the polishing end point of the workpiece W using the polishing end point detection device 70 will be described. FIG. 4 is a flowchart showing the procedure for detecting the polishing end point of the workpiece W. In the following, the case of using a silicon substrate where a silicon dioxide film (hereinafter referred to as a “thermal oxide film”) as a layer to be polished is formed on the surface as the workpiece W will be described as an example, but the substrate of the workpiece W and the film type are not limited thereto.

### (Reference Measurement)

First, the reference intensity is calculated using a sample workpiece in which the optical constant such as a refractive index and an attenuation rate is known (step S1).

Specifically, CMP slurry is supplied from the nozzle 6 onto the polishing pad 5, the platen 2 is rotated, and the polishing head 10 holding the sample workpiece is lowered toward the rotating polishing pad 5 to bring the sample workpiece into contact with the polishing pad 5. When bringing the sample workpiece into contact with the polishing pad 5, the polishing head 10 can be in either a rotating state or a stationary (non-rotating) state, but it is preferable to unify the rotation speed of the platen 2, the CMP slurry supply volume, and other reference measurement conditions that can be arbitrarily set in calculating the reference intensity of the sample workpiece with the polishing conditions of the workpiece W described later.

After that, measurement light is irradiated from the lens 73 toward the sample workpiece through the observation window 80, the reflected light from the sample workpiece enters the lens 73 through the observation window 80, and the spectrometer 77 calculates the reference intensity for each wavelength component based on the reflected light from the sample workpiece and the optical constant of the sample workpiece.

As the sample workpiece, one that exhibits reflectance characteristics almost equal to the workpiece W is used. The “reflectance characteristics” is a characteristic relating to the reflected light possessed by the sample workpiece suitable for comparison with the workpiece W in consideration of the respective reflectances of the layer to be polished and the substrate of the workpiece W and the aspects of reflected light caused by the structure of the workpiece W, among others. Therefore, the sample workpiece is not limited to one that is made of the same material as the substrate of the workpiece W and has no film formed on it, as in the present embodiment.

For example, if the workpiece W has a polysilicon film formed between a silicon substrate and a thermal oxide film, the respective refractive indices of silicon and polysilicon are sufficiently close, so a silicon substrate may be used or a silicon substrate on which a polysilicon film is formed may be used as the sample workpiece.

Also, if the workpiece W has a titanium layer of about 100 nm formed between a silicon substrate and a thermal oxide film, light is hardly transmitted from the titanium film to the silicon substrate side, so the substrate material for the sample workpiece may be glass or the like without limiting to silicon as long as the titanium is formed on the top surface.

Furthermore, if the respective refractive indices of the substrate and the layer to be polished formed on the substrate are close as in the case of a workpiece W in which silicon dioxide film is formed on a sapphire substrate, either a substrate with no film formed or a substrate with a layer to be polished formed may be used for the sample workpiece.

### (CMP Polishing)

Next, the controller activates the CMP device 1 and starts CMP polishing of the workpiece W to flatly polish the thermal oxide film formed on one surface of the workpiece W attached to the lower surface of the polishing head 10 (step S2). CMP polishing of the workpiece W is performed by contacting of the silicon dioxide film of the workpiece W with the polishing pad 5 in a state where the platen 2 and the polishing head 10 are both rotating while the CMP slurry is supplied onto the polishing pad 5.

### (Spectral Waveform Generation)

Next, while the workpiece W is being polished, the light source unit 76 irradiates measurement light and the spectrometer 77 generates a spectral waveform based on the reflected light from the workpiece W (step S3).

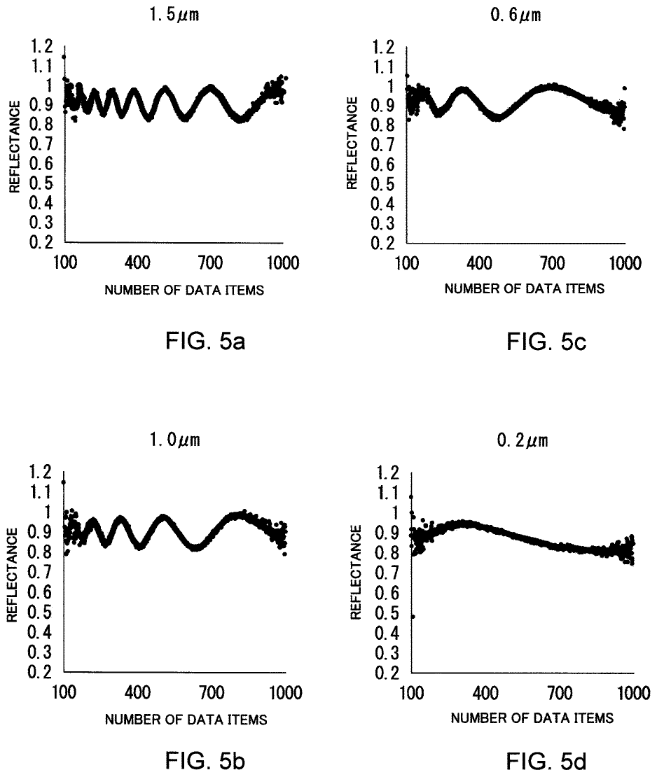

The spectral waveforms shown in FIG. 5 are graphs in which the number of data items (equivalent to the wavelength of reflected light. Hereafter simply referred to as “wavelength”) is set for the horizontal axes and the reflectance calculated by dividing the intensity of the reflected light from the workpiece W by the reference intensity of the sample workpiece calculated in step S1 is set for the vertical axes. FIG. 5(a) shows the spectral waveform when the film thickness of the thermal oxide film is 1.5 μm, FIG. 5(b) shows the spectral waveform when the film thickness of the thermal oxide film is 1.0 μm, FIG. 5(c) shows the spectral waveform when the film thickness of the thermal oxide film is 0.6 μm, and FIG. 5(d) shows the spectral waveform when the film thickness of the thermal oxide film is 0.2 μm.

### (Calculation of Film Thickness)

Next, the detection section 72 calculates the film thickness of the thermal oxide film in the workpiece W being polished at predetermined intervals (step S4).

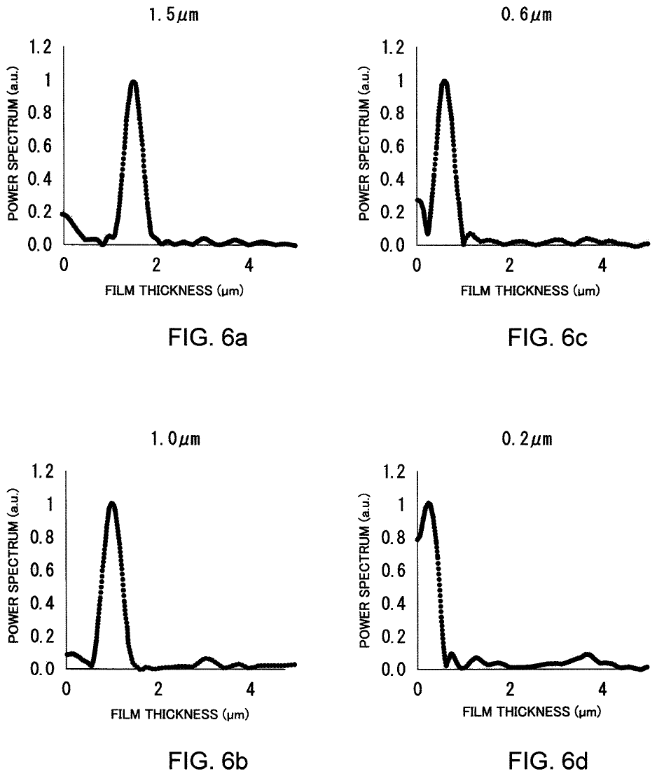

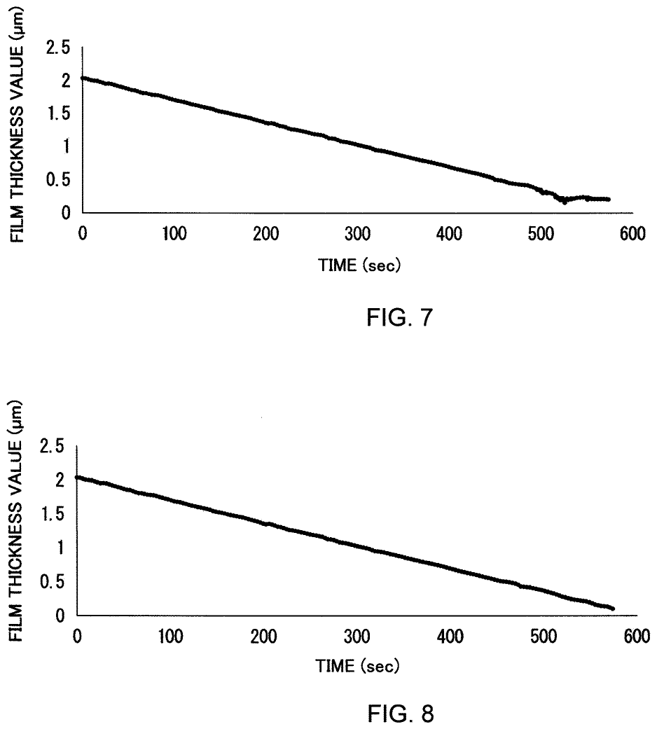

Specifically, the detection section 72 calculates the film thickness of the thermal oxide film during polishing by using Fourier analysis on the spectral waveform generated by the spectrometer 77. The frequency spectra showing the relationship between the film thickness of the thermal oxide film and the intensity of the frequency components, which spectra are obtained by applying Fourier analysis to the spectral waveforms in FIG. 5(a) to (d), are shown in FIG. 6(a) to (d), and a graph showing the trend of continuous changes in the thermal oxide film's film thickness decreasing as the polishing progresses, is shown in FIG. 7. Furthermore, FIG. 8 is a graph showing the trend of changes in the film thickness of the thermal oxide film when curve fitting with theoretical waveforms using the optimization method has been applied at a film thickness of 1.0 μm or less to the graph in FIG. 7.

Next, the detection section 72 determines whether the film thickness of the thermal oxide film in the workpiece W during polishing, calculated in step S4, has reached a predetermined threshold value (step S5).

Specifically, when the signal peak of the frequency spectrum in the film thickness of the thermal oxide film exceeds a predetermined threshold value, the detection section 72 estimates the film thickness of the thermal oxide film corresponding to that signal peak as the film thickness of the thermal oxide film in the workpiece W during polishing. It should be noted that, in order to detect the film thickness smoothly, the detection section 72 may estimate the film thickness of the workpiece W during polishing from the trend of changes in the film thickness of the thermal oxide film in an auxiliary manner.

If the film thickness of the thermal oxide film in the workpiece W during polishing is smaller than a predetermined threshold value (No in step S5), the step is returned to step S4 and the detection section 72 again calculates the film thickness of the thermal oxide film in the workpiece W during polishing.

### (Polishing End Point Detection)

If the film thickness of the thermal oxide film in the workpiece W during polishing reaches a predetermined value (Yes in step S5), the detection section 72 determines that the film thickness of thermal oxide film has reached the target thickness and the polishing end point has been reached, and outputs a stop signal for the CMP device 1 to the controller 7 to terminate CMP polishing for the workpiece W (step S6).

In the present embodiment, the case in which the difference in the refractive index between the substrate (silicon substrate) of the workpiece W and the layer to be polished (thermal oxide film) is relatively large has been described as an example, but the present embodiment can also be applied to cases where the difference in the refractive index between the substrate of the workpiece W and the layer to be polished is relatively small. Hereinafter, the case in which a sapphire substrate on which a thermal oxide film is formed is polished (a variant example) will be described as an example. The refractive indices of the thermal oxide film, the silicon substrate, and the sapphire substrate at a wavelength of 632.8 nm are 1.457, 3.882, and 1.770, respectively.

In the present variant example, a sapphire substrate on which no thermal oxide film was formed was used as the sample workpiece, and a sapphire substrate on which a thermal oxide film was formed was used as the workpiece W. In the variant example, the reference measurement conditions for calculating the reference intensity and the polishing conditions of the workpiece W were set the same as in the embodiment described above, except for the points described above.

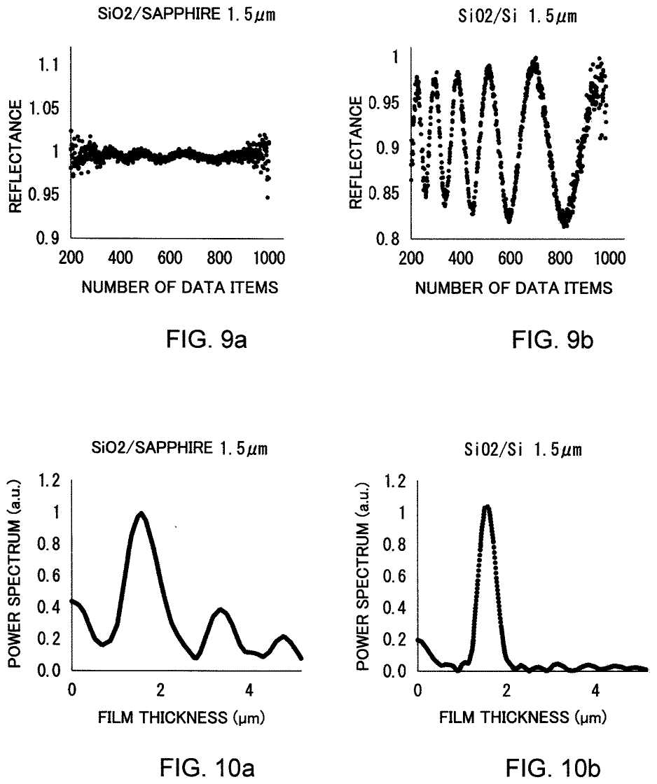

FIG. 9(a) shows the spectral waveforms according to the present variant example, and FIG. 9(b) shows the spectral waveforms according to the embodiment described above. According to FIG. 9(a) and 9(b), it can be seen that the spectral waveform corresponding to the workpiece W where the difference in the reflectance between the substrate and the thermal oxide film is relatively small has a smaller amplitude of the reflectance, compared to the workpiece W where the difference in the reflectance between the substrate and the thermal oxide film is relatively large.

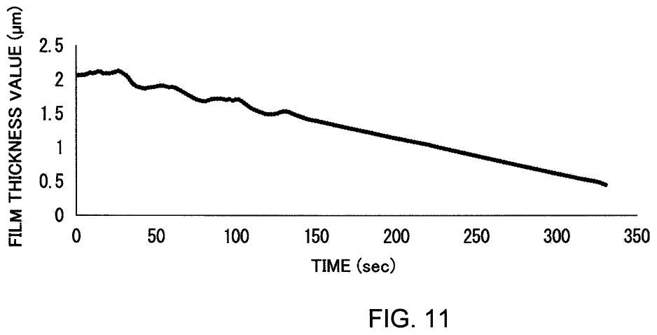

Additionally, the frequency spectra obtained by applying Fourier analysis to the spectral waveforms shown in FIG. 10(a) to 10(b) are shown in FIG. 9(a) to 9(b). According to FIG. 9(a) to 9(b), it can be seen that the frequency spectrum corresponding to the workpiece W where the difference in the reflectance between the substrate and the thermal oxide film is relatively small, when compared the frequency spectrum corresponding to workpiece W where the difference in the reflectance between the substrate and the thermal oxide film is relatively large, contains more noise, and also has wider signal peaks, so that the analysis tends to be difficult. Such a tendency is greater for workpieces W where the difference in the bending rate between the substrate and the thermal oxide film is small when there is a slope at the vibration center of the reflectance of the spectral waveform. Therefore, when the difference in the refractive index between the substrate and the thermal oxide film is small and the influence of disturbances is large in calculating the film thickness as in Comparative Example 1, by calculating the reference intensity using a sample workpiece that exhibits the same refractive index characteristics as the workpiece W and excluding the slope at the vibration center of the reflectance of the spectral waveform, it is possible to obtain with high accuracy a graph showing the trend of changes in the thermal oxide film's film thickness decreasing as the polishing progresses, as shown in FIG. 11. In FIG. 11, only Fourier analysis is applied up to a film thickness of 1.5 μm, while an optimization method is applied in addition to Fourier analysis for a film thickness of 1.5 μm or less.

Next, the features of each of the above processes of reference measurement (step S1), spectral waveform generation (step S3), and film thickness calculation (step S4) will be described in detail by comparing them with various comparative examples.

### Influence of the Reflectance Characteristics of the Sample Workpiece on the Calculation of Film Thickness

In acquiring spectral waveforms related to the reflected light from a silicon substrate on which a thermal oxide film is formed as in the embodiment described above, the spectral waveforms, frequency spectra, and film thickness analysis results were compared between the case where the reference intensity was calculated using the silicon substrate as the sample workpiece and the case where the reference intensity was calculated using a mirror (Comparative Example 1).

In Comparative Example 1, a mirror was used in place of the sample workpiece, a non-rotating mirror was disposed above the observation window 80 in the CMP device 1, measurement light was irradiated through the observation window 80 from below the platen 2 in a non-rotating state toward the mirror, and based on the reflected light from the mirror, the spectrometer 77 calculated the reference intensity of the mirror. Also, in the reference measurement, no CMP slurry was supplied on the polishing pad 5. In Comparative Example 1, the reference measurement conditions for calculating the reference intensity and the polishing conditions of the workpiece W (silicon substrate on which a thermal oxide film was formed) were set the same as in the embodiment described above, except for the points described above.

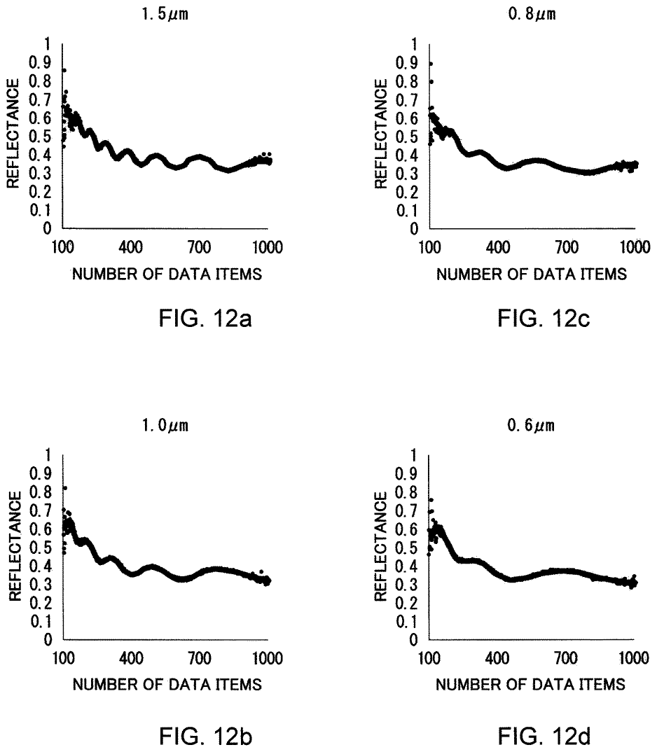

FIG. 12 shows spectral waveforms in which the wavelength of the reflected light from the workpiece W is set for the horizontal axes and the reflectance calculated by dividing the intensity of the reflected light from the workpiece W by the reference intensity calculated based on the reflected light from the mirror is set for the vertical axes. FIG. 12(a) shows the spectral waveform when the film thickness of the thermal oxide film is 1.5 μm, FIG. 12(b) shows the spectral waveform when the film thickness of the thermal oxide film is 1.0 μm, FIG. 12 (c) shows the spectral waveform when the film thickness of the thermal oxide film is 0.8 μm, and FIG. 12(d) shows the spectral waveform when the film thickness of the thermal oxide film is 0.6 μm. According to FIG. 12(a) to 12(d), a peculiar peak is present in the vicinity of the wavelength approximately 100 nm, and the vibration center of the spectral waveform is inclined in such a way that the reflectance decreases as the wavelength increases. This is considered to be because, because the reference intensity was calculated using a mirror, the reflectance characteristics due to the workpiece W material, the waviness of the workpiece W, vibrations caused by the rotation of the polishing pad 5, thickness variations in the observation window 80, the presence or absence of CMP slurry, and the like had an influence.

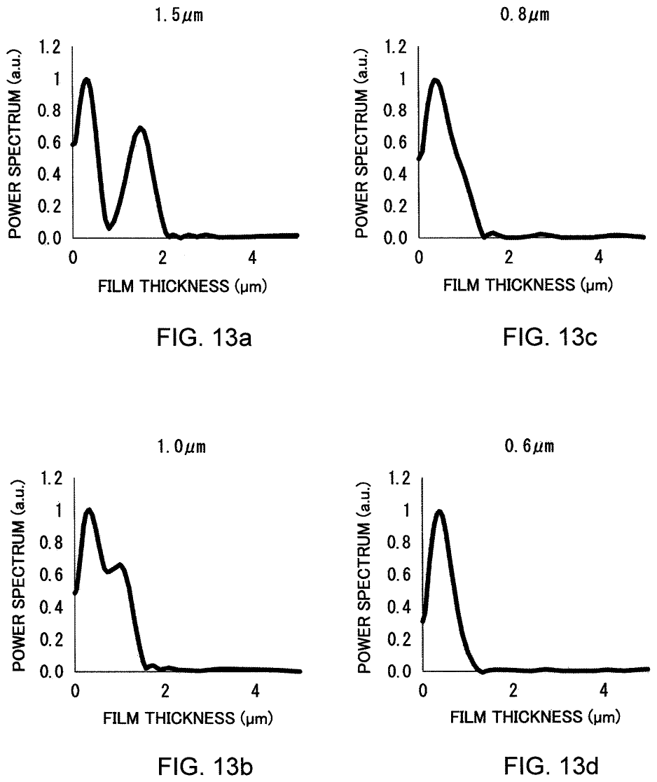

Also, the frequency spectra showing the relationship between the film thickness of the thermal oxide film and the intensity of the frequency components, which spectra are obtained by applying Fourier analysis to the spectral waveforms in FIG. 12(a) to 12(d), are shown in FIG. 13 (a) to 13(d). According to FIG. 13(a) to 13(d), at film thicknesses of 1.5 μm and 1.0 μm, there is one signal peak on the thin film side (the vicinity of the film thickness approximately 0.5 μm) that is more prominent than the signal peak corresponding to the film thickness, and at film thicknesses of 0.8 μm and 0.6 μm, the signal peak corresponding to the film thickness and the prominent signal peak on the thinner film side are integrated and widened. These are thought to be due to the influence of the differences between the reflectance characteristics of the sample workpiece and the reflectance characteristics of the workpiece W.

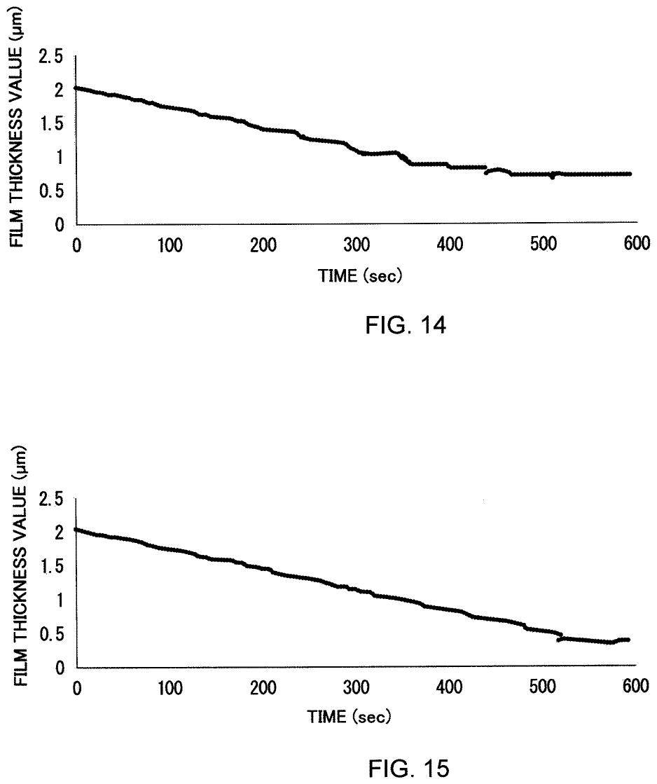

In addition, FIG. 14 shows a graph showing the trend of changes in the thermal oxide film's film thickness decreasing as the polishing progresses. According to FIG. 14, it can be seen that the film thickness cannot be stably measured at about 1 μm or less. Also, FIG. 15 is a graph showing the trend of changes in the film thickness of the thermal oxide film when curve fitting with theoretical waveforms using the optimization method has been applied at a film thickness of 1.5 μm or less to the frequency spectrum in FIG. 14. According to FIG. 15, it can be seen that the film thickness cannot be stably measured at about 0.5 μm or less. These are considered to be due to the presence of the signal peak in the vicinity of a film thickness of 0.5 μm which is appearing in the frequency spectrum described above.

On the other hand, in the present embodiment, according to FIG. 5(a) to 5(d), it can be seen that the spectral waveforms contain no peculiar peaks and the center of vibration of the spectral waveforms (reflectance of approximately 0.9) is flat. Also, according to FIG. 6(a) to 6(d), it can be seen that only one prominent signal peak corresponding to the film thickness appears in the frequency spectra. Also, according to FIG. 7, it can be seen that the film thickness can be measured stably up to about 0.5 μm, where the trend of changes in the thermal oxide film's film thickness decreasing as polishing progresses is regular. Furthermore, according to FIG. 8, it can be seen that the film thickness can be measured up to about 0.11 μm, where the trend of changes in the film thickness of the thermal oxide film is regular.

### Effect of a Polishing Agent Contained in Slurry on the Calculation of Film Thickness

The spectral waveforms, frequency spectra, and film thickness analysis results were compared between the case where CMP slurry was interposed during polishing as in the embodiment described above and the case where ultrapure water (DIW) not containing a polishing agent was interposed during polishing (Comparative Example 2).

In Comparative Example 2, a silicon substrate was used as the sample workpiece, and the reference intensity of the sample workpiece was measured while the sample workpiece in a stationary (non-rotating) state was in contact with the polishing pad 5 in a stationary (non-rotating) state while supplying ultrapure water. In Comparative Example 2, the reference measurement conditions for calculating the reference intensity and the polishing conditions of the workpiece W were set the same as in the embodiment described above, except for the points described above.

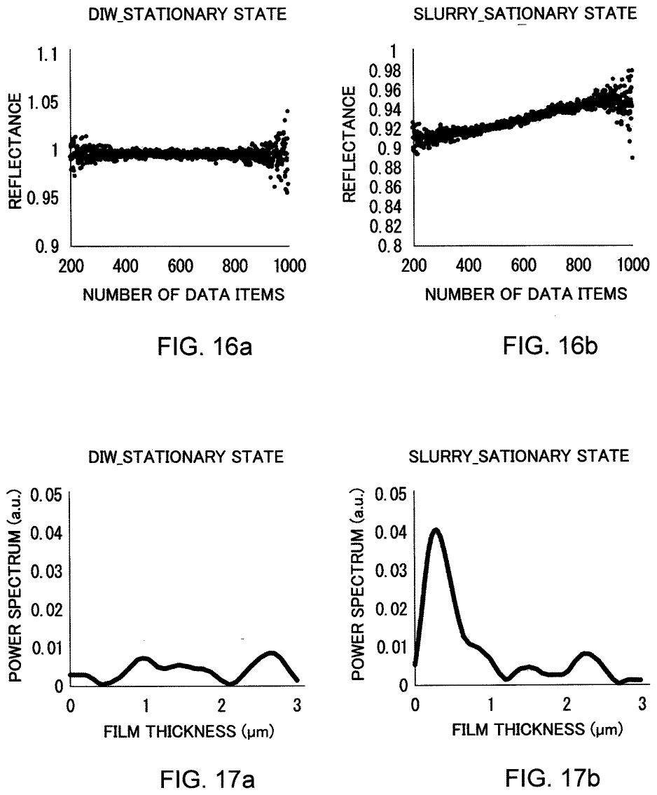

FIG. 16(a) shows the spectral waveform according to Comparative Example 2, and FIG. 16(b) shows the spectral waveform according to the embodiment described above. According to FIG. 16(a), it can be seen that the vibration center of the reflectance is stable in the vicinity of the reflectance 1 regardless of the wavelength. On the other hand, according to FIG. 16(b), it can be seen that the vibration center of the reflectance is inclined in such a way that the reflectance increases as the wavelength increases. Such a inclination is considered to be due to the fact that the slurry contains a polishing agent, and although it is about 0.05 for the entire wavelength, for example, in the workpiece W where the difference in the reflectance between the substrate and the layer to be polished is relatively small as in Comparative Example 1, the effect on the calculation of film thickness is unavoidable.

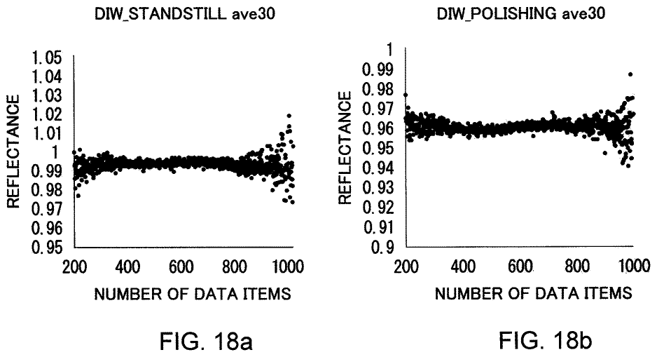

FIG. 17(a) and 17(b) are frequency spectra obtained by applying Fourier analysis to the spectral waveforms shown in FIG. 16(a) and 16(b). FIG. 18 is frequency spectra obtained by applying Fourier analysis to the frequency spectrum shown in FIG. 17(a). With respect to FIG. 17(a) and 17(b), unlike other frequency spectra described herein, the vertical axes are not standardized by the maximum signal peak. Comparing FIG. 17(a) and 17(b), a peculiar signal peak appears in the vicinity of the film thickness approximately 0.5 μm in FIG. 17(b), which may interfere with the calculation of film thickness. Thus, if slurry containing no polishing agent is used when measuring the reference intensity and slurry containing a polishing agent is used during polishing, an effect on the calculation of film thickness cannot be avoided. Therefore, it is preferable to use slurry containing a polishing agent in the same manner as when polishing even when measuring the reference intensity.

### Influence of the Rotation of Platen on the Calculation of Film Thickness

The average spectral waveform of 30 times was compared between the case where the platen 2 was rotated at the reference measurement as in the embodiment described above and the case where the platen 2 was not rotated at the reference measurement (Comparative Example 3).

In Comparative Example 3, a silicon substrate was used as the sample workpiece, and the reference intensity of the sample workpiece was measured while the sample workpiece in a rotating state was in contact with the polishing pad 5 in a stationary state (non-rotating state) while supplying the CMP slurry. It should be noted that in Comparative Example 3, the reference measurement conditions for calculating the reference intensity and the polishing conditions of the workpiece W were set the same as in the embodiment described above, except for the points described above.

FIG. 18(a) shows the spectral waveform according to Comparative Example 3 and FIG. 18(b) shows the spectral waveform according to the embodiment described above. According to FIG. 18(a), it can be seen that the vibration center of the reflectance is stable in the vicinity of the reflectance 0.995. On the other hand, according to FIG. 18(b), it can be seen that the vibration center of the reflectance is in the vicinity of the reflectance 0.96 and that, when the wavelength is 400 nm or less, the reflectance is inclined in such a way that the reflectance increases as the frequency decreases. Such an inclination is considered to be because: the spot diameter of the measurement light is around 3 mm, while the inner diameter of the observation window 80 is approximately 2.5 mm, so the measurement light and reflected light pass within a circle of 2.5 mm diameter corresponding to the observation window 80 when the polishing pad 5 is in a stationary state, whereas when the polishing pad 5 rotates, the observation window 80 rotates together with the polishing pad 5 and moves approximately 5.2 mm in the circumferential direction when the radius of rotation of the observation window 80 is 165 mm and the exposure time of the light source unit 76 is 5 msec, so the measured light and reflected light pass through a wider area than in Comparative Example 3, which is approximately 4.3 times larger. Furthermore, with respect to the inclination of the vibration center of the reflectance in the low wavelength range, the fact that the thickness of the slurry on the polishing pad 5 in the rotating state and the thickness of the slurry on the polishing pad 5 in the stationary state differ is also considered to be a cause of the above-mentioned inclination.

This way, the polishing end point detection device 70 according to the present embodiment described above is a polishing end point detection device 70 for detecting the polishing end point when performing CMP polishing of the thermal oxide film of the workpiece W by bringing the workpiece W into contact with the polishing pad 5, and is configured to include a measuring section 71 for irradiating the workpiece W with measurement light during polishing of the workpiece W, and dispersing the reflected light from the workpiece W to obtain a spectral waveform that indicates the relationship between the wavelength of the reflected light and a reflectance, which is the ratio of the intensity of the reflected light and the reference intensity for each wavelength component acquired in advance, and a detection section 72 for calculating the film thickness of the thermal oxide film by applying Fourier analysis to the spectral waveform, and to calculate the reference intensity by bringing a sample workpiece exhibiting reflectance characteristics almost same as the substrate of the workpiece W into contact with the polishing pad 5 with CMP slurry interposed between the sample workpiece and the rotating polishing pad 5, by irradiating the sample workpiece with measurement light through an observation window 80 of the polishing pad 5 by the measuring section 71, and by dispersing the reflected light from the sample workpiece.

With this configuration, it is possible to accurately detect the film thickness of a thin workpiece W by using a sample workpiece that exhibits almost the same reflectance as the workpiece W and calculating the reference intensity of the sample workpiece by unifying the reference measurement conditions, such as the presence or absence of a polishing agent in the slurry, which may affect the calculation of film thickness, and the rotation or standstill of the platen 2, with the polishing conditions for polishing the workpiece W.

Also, the CMP device 1 according to the present embodiment is configured to include a polishing end point detection device 70.

With this configuration, it is possible to accurately detect the polishing end point of a thin workpiece W.

Also, the polishing end point detection method according to the present embodiment described above is a polishing end point detection method for detecting the polishing end point when performing CMP polishing of the thermal oxide film of the workpiece W by bringing the workpiece W into contact with a polishing pad 5, and is configured to include the step of irradiating the workpiece W with measurement light during polishing of the workpiece W, and dispersing the reflected light from the workpiece W to obtain a spectral waveform that indicates the relationship between the wavelength of the reflected light and a reflectance, which is the ratio of the intensity of the reflected light and the reference intensity for each wavelength component acquired in advance, and the step of calculating the film thickness of the thermal oxide film by applying Fourier analysis to the spectral waveform, and to calculate the reference intensity by bringing a sample workpiece exhibiting reflectance characteristics almost same as the workpiece W into contact with the polishing pad 5 with slurry interposed between the sample workpiece and the rotating polishing pad, by irradiating the sample workpiece with measurement light through an observation window 80 of the polishing pad 5, and by dispersing the reflected light from the sample workpiece.

With this configuration, it is possible to accurately detect the film thickness of a thin workpiece W by using a sample workpiece that exhibits reflectance almost same as the workpiece W and calculating the reference intensity of the sample workpiece by unifying the reference measurement conditions, such as the presence or absence of a polishing agent in the slurry, which may affect the calculation of film thickness, and the rotation or standstill of the platen 2, with the polishing conditions for polishing the workpiece W.

It should be noted that the present invention may be modified in various ways so long as the spirit of the present invention is not deviated, and it is a matter of course that the present invention extends to such modified versions.

In the present embodiment described above, Fourier analysis is applied to the spectral waveform to calculate the film thickness of the layer to be polished, but, without being limited thereto, for example, fast Fourier transform (FFT) or curve fitting with a theoretical waveform may be applied. When applying curve fitting with a theoretical waveform, prepare theoretical waveforms of the spectral waveform in advance through an experiment or the like, find the theoretical waveform that best matches the spectral waveform obtained by the measuring section 71, and convert it into the film thickness of the layer to be polished.

In addition, the present invention also applicable to workpieces W made of a material other than the material exemplified in the present embodiment described above, such as workpieces W made of a material containing silicon carbide (SiC) or workpieces W made of gallium nitride (GaN). As the sample workpieces corresponding to these, sample workpieces that exhibit reflectance characteristics that are almost equal to those of these workpieces W are used.

### REFERENCE SIGNS LIST

1: CMP device
2: Platen
3: Rotation axis
4: Motor
5: Polishing pad
6: Nozzle
7: Controller
10: Polishing head
10a: Rotation axis
20: Head body
21: Rotating section
30: Carrier
30a: Lower surface
31: Air line
32: Carrier pressing means
40: Retainer ring
41: Retainer ring holder
41a: Housing pocket (housing section)
42: Snap ring
43: Retainer pressing member
44: Retainer pressing means
50: Membrane film
60: Backing film
70: Polishing end point detection device
71: Measuring section
72: Detection section
73: Lens
74, 75: Optical fiber
76: Light source unit
77: Spectrometer
80: Observation window
A: Air chamber
W: Workpiece

1. A polishing end point detection device for detecting a polishing end point when performing CMP polishing of a layer to be polished of a workpiece by bringing the workpiece into contact with a polishing pad, by comprising:
a measuring section for irradiating the workpiece with measurement light during polishing of the workpiece, and dispersing reflected light from the workpiece to obtain a spectral waveform indicating a relationship between a wavelength of the reflected light and a reflectance, which is a ratio of an intensity of the reflected light and a reference intensity for each wavelength component acquired in advance; and
a detection section for calculating a film thickness of the layer to be polished based on the spectral waveform,
wherein the reference intensity is calculated by bringing a sample workpiece exhibiting reflectance characteristics almost same as the workpiece into contact with the polishing pad with slurry interposed between the sample workpiece and the rotating polishing pad, by irradiating the sample workpiece with measurement light through an observation window of the polishing pad by the measuring section, and by dispersing reflected light from the sample workpiece.

2. The polishing end point detection device according to claim 1, wherein:
the detection section calculates a film thickness of the layer to be polished by applying Fourier analysis to the spectral waveform.

3. The polishing end point detection device according to claim 1, wherein:
the detection section calculates a film thickness of the layer to be polished by applying curve fitting with a theoretical waveform of the spectral waveform to the spectral waveform.

4. A CMP device comprising the polishing end point detection device according to claim 1.

5. A polishing end point detection method for detecting a polishing end point when performing CMP polishing of a layer to be polished of a workpiece by bringing the workpiece into contact with a polishing pad, comprising the steps of:
irradiating the workpiece with measurement light during polishing of the workpiece, and dispersing reflected light from the workpiece to obtain a spectral waveform indicating a relationship between a wavelength of the reflected light and a reflectance, which is a ratio of an intensity of the reflected light and a reference intensity for each wavelength component acquired in advance; and
calculating a film thickness of the layer to be polished based on the spectral waveform,
wherein the reference intensity is calculated by bringing a sample workpiece exhibiting reflectance characteristics almost same as the workpiece into contact with the polishing pad with slurry interposed between the sample workpiece and the rotating polishing pad, by irradiating the sample workpiece with measurement light through an observation window of the polishing pad, and by dispersing reflected light from the sample workpiece.
